(19) United States
(12) Patent Application Publication
(10) Pub. No.: US 2026/0180287 A1
(43) Pub. Date: Jun. 25, 2026

(54) Low noise non-resonant gain structure semiconductor lasers

(71) Applicant: Pavilion Integration Corporation, San Jose, CA (US)

(72) Inventors: Ningyi Luo, San Jose, CA (US); Haiwen Wang, San Jose, CA (US); Jihchuang Robin Huang, San Jose, CA (US)

(73) Assignee: Pavilion Integration Corporation, San Jose, CA (US)

(21) Appl. No.: 19/127,680

(22) PCT Filed: Dec. 11, 2023
(86) PCT No.: PCT/IB2023/062507

§ 371 Date: May 6, 2025

Related U.S. Application Data
(60) Provisional application No. 63/386,898, filed on Dec. 10, 2022.
(60) Provisional application No. 63/480,689, filed on Jan. 19, 2023.

(51) Int. Cl. H01S 5/14; H01S 5/00; H01S 5/028; H01S 5/04; H01S 5/34

(52) U.S. Cl. CPC H01S 5/141; H01S 5/0092; H01S 5/028; H01S 5/041; H01S 5/34

(57) ABSTRACT

Some semiconductor gain chips used for both optically pumped and electrically pumped semiconductor lasers contain transparent layers for cooling or other purposes. These layers may cause unwanted etalon effect if one or more of the transparent layers are inside the laser cavity. The etalon effect may cause high laser output noise. The present invention provides ways to make low noise lasers with such semiconductor gain chips.

### BACKGROUND

Semiconductor lasers are growing rapidly in recent years. Heat removal from semiconductor gain chips is very important for increasing laser output power. One way to remove the heat is letting the quantum well/dot structure be in thermal contact with a transparent optical grade material with good thermal conductivity, such as diamond, SiC, etc. FIG. 1 shows an example of a semiconductor gain chip. Item 1 in the center is a quantum well (QW) structure sandwiched between items 2 and 3, which are two transparent SiC layers, for cooling. Surface A of the gain chip is coated for high reflection of the lasing wavelength and anti-reflection of the pump wavelength. Surface B is antireflection coated for the laser wavelength. A laser with such a QW gain chip is shown in FIG. 2. Item 21 is the QW gain chip and forms a laser cavity with item 23, which is the output coupler. Item 22 is a birefringent filter plate (BFP) positioned at the Brewster angle. Thus the laser lases in the p-polarization. Item 24 is the pump beam. Item 25 is the output laser beam.

FIG. 3 shows the transmission curve of a BFP with two different thicknesses for p polarized beam. Its free spectral range is so wide that adjacent transmission peaks are outside of the gain bandwidth of the semiconductor gain chip. The laser lases at the wavelengths around the transmission peak of the BFP.

Surfaces of SiC layers (items 2 and 3) are parallel. They act like etalons. FIG. 4 shows an example of the transmission curve of the two SiC etalons assuming they are nominally 0.5 mm thick with slight thickness difference. The etalon effect is sometimes unwanted. For example, the laser may hop from single longitudinal mode (SLM) to multi-longitudinal mode (MLM), or vice versa. Or lasing longitudinal modes may hop from one etalon transmission peak to another. Or the lasing longitudinal modes cover more than one etalon transmission peak, and the longitudinal modes at different etalon transmission peaks compete for gains. If the laser is used for intracavity harmonic generation, the output harmonic beam is very noisy. For example, the intracavity second harmonic peak-peak noise is usually >40%. An example of the intracavity second harmonic output from such a laser is shown in FIG. 13.

### SUMMARY OF THE INVENTION

The present invention provides ways to reduce the semiconductor laser output noise.

### DESCRIPTION OF THE DRAWING

The invention is described with respect to a drawing in several figures, of which:

FIG. 1 shows an example of a semiconductor gain chip;

FIG. 2 shows a laser with a quantum well (QW) gain chip;

FIG. 3 shows the transmission curve of a birefringent filter plate (BFP);

FIG. 4 shows an example of the transmission curve of two SiC etalons;

FIG. 5a shows a semiconductor gain chip;

FIG. 5b shows details at the QW structure of a semiconductor gain chip;

FIG. 6(a) shows a laser using a tilted gain chip;

FIG. 6(b) shows a laser using a tilted gain chip with a rearranged optical arrangement;

FIG. 7 shows an example of intracavity second harmonic generation;

FIG. 8 shows an example of intracavity third harmonic generation (THG);

FIG. 9 shows a configuration that uses a narrow band volume Bragg grating (VBG);

FIG. 10 shows a configuration with a gain chip tilted at Brewster angle;

FIG. 11 shows a configuration with a narrow bandpass filter;

FIG. 12 shows a configuration with a gain chip tilted at Brewster angle and a narrow bandpass filter; and

FIG. 13 shows an intracavity second harmonic output.

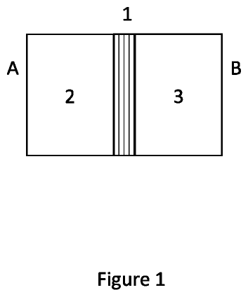

Within the figures, where possible a like element is denoted with a like reference numeral.

### DETAILED DESCRIPTION

Resonant periodic gain (RPG) architecture is usually used to make QW structure, in which QW positions are aligned with antinodes of the laser standing wave. More longitudinal modes would be able to lase if the gain chip QW positions are not in resonance with laser standing wave antinodes. We do this by arranging the apparatus so that the gain chip QW positions are not aligned with antinodes of the laser standing wave. Increasing the cavity length, which would decrease the longitudinal mode separation, would also allow more longitudinal modes to lase. More lasing longitudinal modes averages out noises caused by mode competition and hopping. This configuration can be used for intracavity harmonic generation. When the cavity optical path length L (sum of the products of the lengths of materials inside cavity including air and their respective refractive indices) satisfies condition 1, the laser intracavity second harmonic output peak-peak noise can be reduced to <10% with non-resonant gain structure gain chips.

$$L > 50 c / R \qquad ( 1 )$$

where c is the speed of light and R is the maximum free spectral range of etalons (in Hertz) formed by the heat removing transparent layers of the gain chip.

Etalon effect is the result of the interference of the multi-reflected beams. It requires good overlap among the multi-reflected beams. If the gain chip is tilted with a large enough angle with regard to the laser beam, the overlap among the multi-reflected beams is minimized. Therefore, the transparent layer etalon effect is weak.

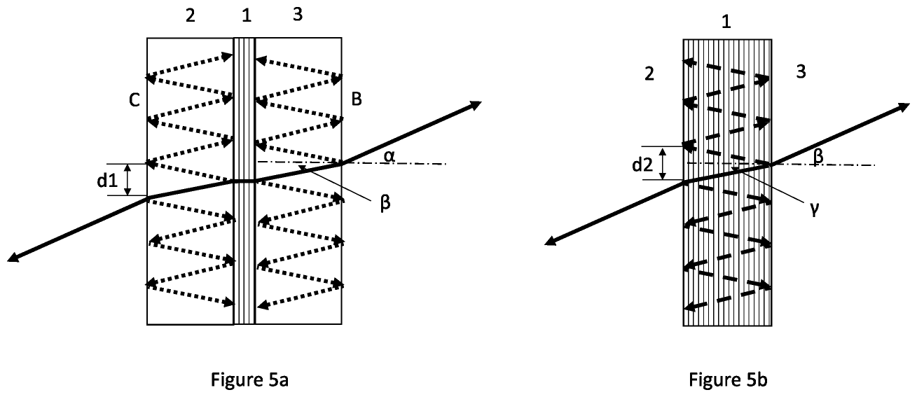

FIG. 5a shows a semiconductor gain chip that can be more conveniently configured to a tilted design. Item 1 in the center is a quantum well (QW) structure sandwiched between items 2 and 3, which are two transparent SiC layers, for cooling. Surface C of the gain chip is coated for anti-reflection of both the laser wavelength and the pump wavelength. Surface B is antireflection coated for the laser wavelength. Angles α, β, are beam angles in the air and SiC, respectively. The dotted arrow lines are multi-reflections in SiC. The overlap among the multi-reflections decreases with increasing angle β, and hence etalon effect diminishes.

FIG. 5b shows some details at the QW structure. Angle γ is the beam refractive angle in the QW structure. The dashed arrow lines are multi-reflections in the QW structure. Resonant periodic gain architecture is usually used for making the QW structure. The QW structure can be considered an etalon because the two surfaces are parallel. Its free spectral range is very large. The lasing wavelengths are around its transmission peak. However, its transmission peak shifts when it is tilted because the effective thickness becomes Tcos(γ), where T is the thickness of the QW structure. The QW structure thickness should be increased to or close to 1/cos(γ)×the optimal thickness for normal incidence to reduce laser cavity loss at the QW structure. (By “close to” we mean “within plus or minus 5%”.)

The gain structure is no longer in RPG structure when tilted if the QW layers are still grown parallel to the outer surfaces. Because of the tilt, the gain chip QW positions are not aligned with antinodes of the laser standing wave. The gain structure becomes quasi-uniform, which works well for the present invention.

The thickness of SiC is usually 2 orders of magnitude larger than that of the QW structure. It is possible to select an angle β so that the overlap among the multi-reflections inside the SiC is minimized while the overlap among the multi-reflections inside the QW structure is still good. Actually the QW structure is usually so thin that even at the maximum incident angle α of 90°, the multi-reflections inside the QW structure is still good.

For example, choose the thickness of the SiC to be 0.5 mm and the thickness of the QW structure to be 2 μm. Choose angle β to be 6°. The displacement d₁ between adjacent reflections in SiC is 105 μm. The overlap among the multi-reflections in SiC is minimized for a beam with a diameter of about 100 μm or less. The SiC etalon effect is very weak. The angle γ is 4.6° if the QW structure material is GaAs and the laser wavelength is 1.1 μm. The displacement d₂ between adjacent reflections in the QW structure is 0.3 μm. The multi-reflections in the QW structure are still well overlapped. The QW structure etalon effect is still very strong. Beam angles and multi-reflection displacement in FIGS. 5a and 5b are exaggerated for better illustration.

In another configuration, angle α can be chosen to be Brewster angle. No AR coating for the semiconductor gain chip is necessary in this case.

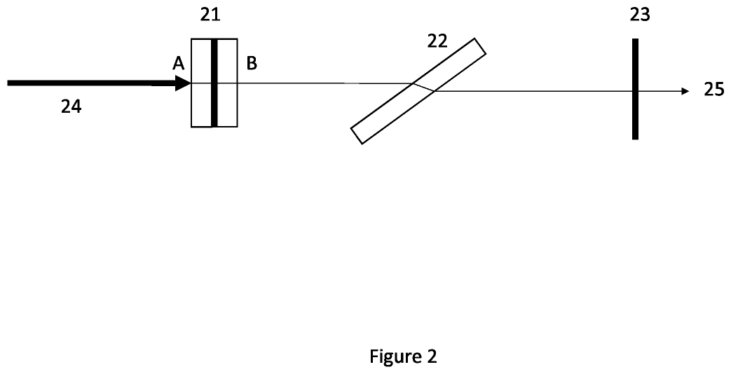

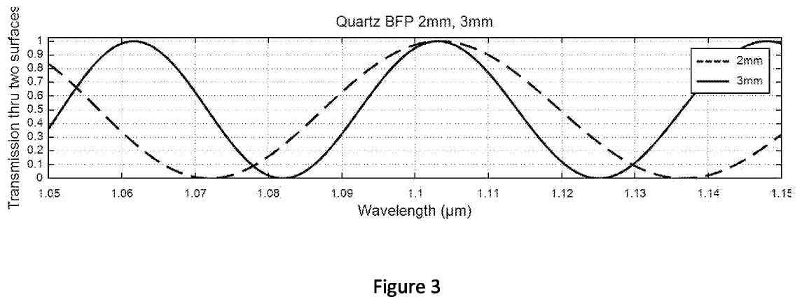

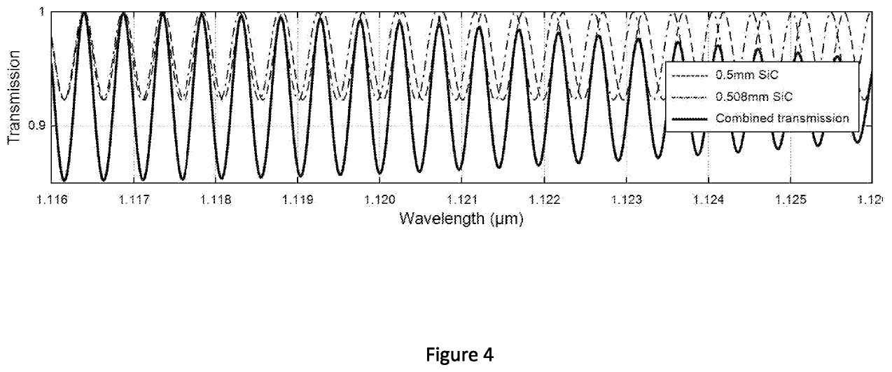

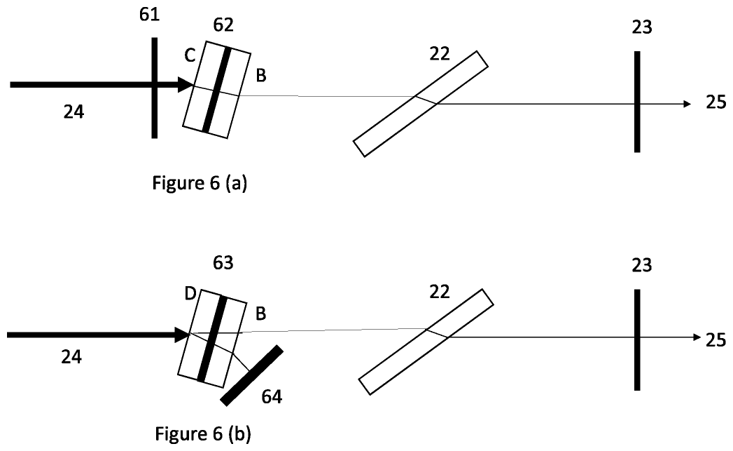

FIG. 6(a) shows a laser using such a tilted gain chip. The laser layout is slightly changed from the one in FIG. 2. Item 61 is a mirror that reflects the laser beam and transmits the pump beam. Item 61 and item 23 (output coupler) form the laser cavity. Item 62 is a gain chip shown in FIG. 5a tilted at an angle with respect to the laser beam. Instead of AR coating on both sides of the gain chip, the gain chip can have high reflective (HR) coating for the lasing wavelength on one side and AR coating on the other side. To adopt this type of gain chip into current tilted gain chip scheme, the optical arrangement in FIG. 6(a) is rearranged as shown in FIG. 6(b). In FIG. 6(b), item 63 is the gain chip with HR coating (D) and AR coating (B). The HR coating can be designed to allow transmission of pump light (24). Cavity mirror 64 can be HR for lasing wavelength only.

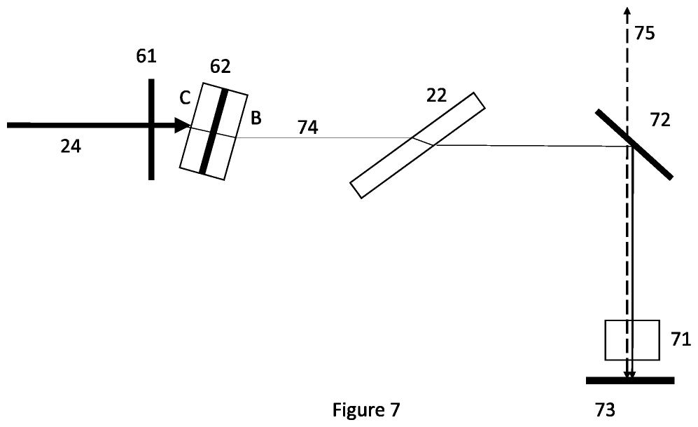

The tilted gain chip configuration can also be used for harmonic generation. FIG. 7 shows an example of intracavity second harmonic generation. Item 71 is a nonlinear optic that generates the second harmonic (SH). Item 72 is a mirror that reflects the fundamental laser beam and transmits the SH. Item 73 is the end cavity mirror that reflects both the fundamental and the second harmonic beams. Item 74 is the oscillating fundamental beam inside the laser cavity. Item 75 is the generated SH and is output through item 72. If tilt angle α (the tilt for item 62) satisfies condition 2, the SiC etalon effect is weak and the laser second harmonic output peak-peak noise can be reduced to <10%.

$$Sin ( α ) > \frac{n D}{10 t} \qquad ( 2 )$$

where n and t are the refractive index and thickness of the transparent layer, respectively, and D is the laser beam diameter at the gain chip.

The BFP transmission peak is relatively flat, the laser cavity without intracavity second harmonic generation (SHG) usually runs in multi-longitudinal mode (MLM) although it may run in SLM under certain conditions. When the laser runs with intracavity SHG, the SHG nonlinear optic also generates a sum frequency of different longitudinal modes. Weaker longitudinal modes are hard to survive because of the additional loss due to the sum frequency. Therefore, the laser can be made to run in SLM. A short cavity is preferred for stable SLM operation.

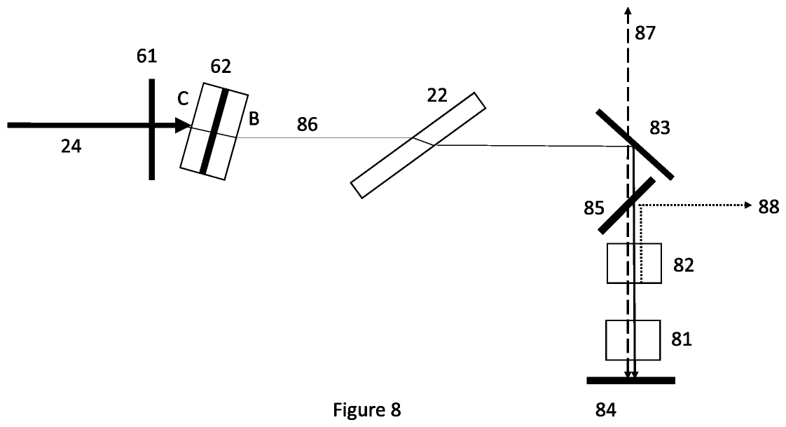

FIG. 8 shows an example of intracavity third harmonic generation (THG). Item 81 is a nonlinear optic that generates the second harmonic (SH). Item 82 is a nonlinear optic that mixes the fundamental and second harmonic beams and generates the third harmonic (TH). Item 83 is a mirror that reflects the fundamental laser beam and transmits the SH. Item 84 is the end cavity mirror that reflects the fundamental and the second harmonic beams. Item 85 is a mirror that reflects the TH and transmits the fundamental and the second harmonic beams. Item 86 is the oscillating fundamental beam inside the laser cavity. Item 87 is the SH and the residual SH is dumped through item 83. Item 88 is the output TH beam. The gain chip item 62 is tilted at an angle that satisfies condition 2. The laser can be made to run in SLM due to frequency mixing, similar to the intracavity SHG. A short cavity is preferred for stable SLM operation.

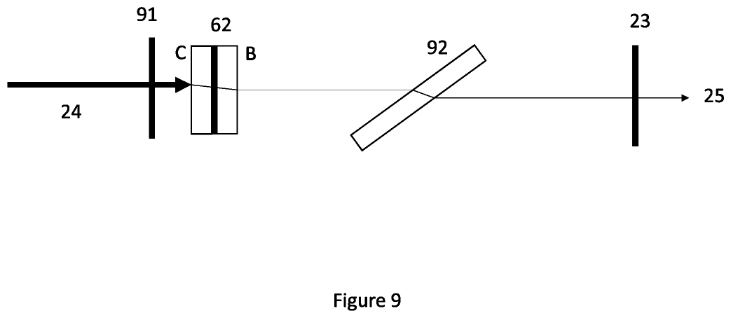

In another configuration, the laser output noises caused by the etalon effect can also be suppressed by introducing a narrow band volume Bragg grating (VBG). An example is shown in FIG. 9. The laser layout is slightly changed from the one in FIG. 6(a). Item 91 is a 0-degree diffraction angle VBG that reflects the laser beam and transmits the pump beam. Item 91 and item 23 (output coupler) form the laser cavity. Item 62 is a gain chip shown in FIG. 5a. Tilting of item 62 is not necessary. Item 92 is a Brewster plate if polarized laser beam is required. Otherwise, item 92 is not necessary. These kind of lasers usually run in MLM although they may run in SLM under certain conditions. The gain chip used for configuration does not require RPG structure.

This kind of lasers can also be used for intracavity harmonic generation, including SHG and THG. If the bandwidth B of item 91 satisfies condition 3, laser intracavity second harmonic output peak-peak noise of <10% can be obtained.

$$B < 0.8 F \qquad ( 3 )$$

where F is the minimum free spectral range of etalons formed by the transparent layers of item 62. The frequency mixing of different longitudinal modes can suppress the weaker longitudinal modes because of this additional nonlinear loss. Therefore, the laser can be made to run in SLM. A short cavity is preferred for stable SLM operation.

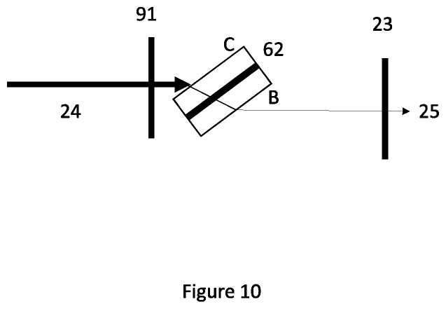

VBGs also work with tilted gain chips. If the gain chip is tilted at Brewster angle, item 92 is no longer needed even if polarized laser beam is required, as shown in FIG. 10. The gain chip, item 62, serves as a polarizer. Coatings on surfaces B and C are not necessary, either. Anti-reflection coating on surface C may help if the pump beam is not polarized, or not p-polarized, or not colinear with the laser beam. This layout can also be used for intracavity harmonic generation, including SHG and THG. The frequency mixing of different longitudinal modes can suppress the weaker longitudinal modes because of this additional nonlinear loss. Therefore, the laser can be made to run in SLM. A short cavity is preferred for stable SLM operation.

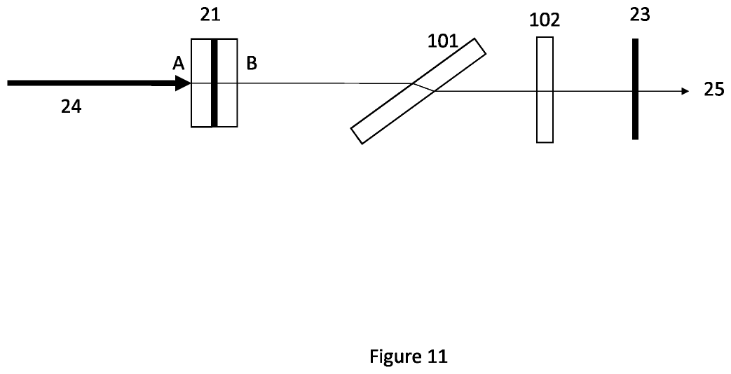

The VBG can be replaced with a narrow bandpass filter. An example is shown in FIG. 11. The laser layout is slightly changed from the layout in FIG. 2. Item 101 is a Brewster plate if a polarized laser beam is required. Item 102 is a narrow band filter. These kind of lasers usually run in MLM although they may run in SLM under certain conditions. The gain chip used for configuration does not require RPG structure.

This kind of lasers can also be used for intracavity harmonic generation, including SHG and THG. If its bandwidth B₂ of the narrow bandpass filter satisfies condition 4, the laser second harmonic output peak-peak noise of <10% can be obtained.

$${B}_{2} < 0.8 {F}_{2} \qquad ( 4 )$$

where F₂ is the minimum free spectral range of etalons formed by the transparent layers of item 21. The frequency mixing of different longitudinal modes can suppress the weaker longitudinal modes because of this additional nonlinear loss. Therefore, the laser can be made to run in SLM.

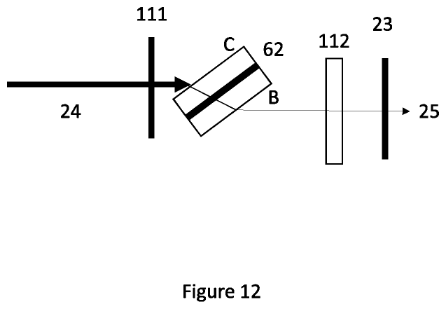

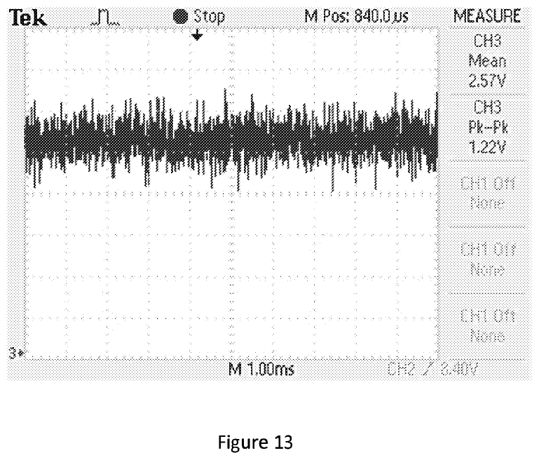

Narrow bandpass filters can also be used in tilted gain chip schemes. An example of using a narrow bandpass filter with a gain chip tilted at Brewster angle is shown in FIG. 12. (The tilt angle can be at the Brewster angle or can be close to the Brewster angle, by which we mean plus or minus eight degrees.) The laser layout is slightly changed from the one in FIG. 10. Item 111 is a mirror that reflects the laser beam while transmitting the pump beam. It forms a laser cavity with item 23, which is the output coupler. Item 112 is a narrow bandpass filter. The laser output is polarized because item 62 serves as a polarizer. These kind of lasers usually run in MLM although they may run in SLM under certain conditions. This kind of lasers can also be used for intracavity harmonic generation, including SHG and THG. The frequency mixing of different longitudinal modes can suppress the weaker longitudinal modes because of this additional nonlinear loss. Therefore, the laser can be made to run in SLM.

Although a specific semiconductor gain chip design and transparent layer material as well as some specific laser designs are used to illustrate the present invention, the present invention is not limited to the specific gain chip design, the specific transparent layer material, or the specific laser designs. The present invention also applies to electrically pumped semiconductor lasers although only optically pumped semiconductor lasers are used for illustration. The semiconductor gain chip can be quantum dot based as well as QW based.

1. An optically pumped or electrically pumped non-resonant gain structure semiconductor laser comprising a laser cavity;
at least one gain chip disposed within the laser cavity;
the at least one gain chip having at least one transparent layer;
the at least one transparent layer defining a maximum free spectral range of etalons (in Hertz) formed thereby;
the laser cavity defining a laser beam;
the laser cavity and laser beam defining a laser standing wave;
the laser disposed such that the gain chip quantum-well (QW) positions are not aligned with antinodes of the laser standing wave;
the laser cavity defining a cavity optical path length L which is the sum of the products of the lengths of materials inside the cavity including air and their respective refractive indices;
the optical path length L selected to be greater than 50c/R, where where c is the speed of light and R is the maximum free spectral range of etalons formed by the at least one transparent layer.

2. The laser of claim 1, wherein the gain chip is a quantum well gain chip or quantum dot gain chip.

3. The laser of claim 1, wherein the transparent layer material is SiC or diamond.

4. The laser of claim 1 comprising at least one additional element in the laser cavity giving rise to intracavity harmonic generation.

5. The laser of claim 4, wherein the intracavity harmonic generation is second harmonic generation or third harmonic generation.

6. An optically pumped or electrically pumped non-resonant gain structure semiconductor laser comprising a laser cavity;
at least one gain chip disposed within the laser cavity;
the at least one gain chip having at least one transparent layer;
the laser cavity defining a laser beam;
the laser beam having a diameter at the gain chip;
the gain chip tilted with regard to the laser beam;
the tilt angle of the gain chip defining an angle α;
the angle α selected to satisfy a condition
$$Sin ( α ) > \frac{nD}{10 t}$$
where n and t are the refractive index and thickness of the at least one transparent layer,
respectively, and D is the laser beam diameter at the gain chip.

7. The laser of claim 6, wherein the gain chip is a quantum well gain chip.

8. The laser of claim 7, wherein the quantum well gain chip does not require a resonant periodic gain architecture.

9. The laser of claim 6, wherein the gain chip is a quantum dot gain chip.

10. The laser of claim 7, wherein the laser beam has a refractive angle γ within the quantum well structure;
the quantum well gain chip defining a quantum well structure, the quantum well structure having a thickness, the thickness of the quantum well structure having some optimal thickness when employed for normal incidence of the laser beam, the thickness of the quantum well structure selected to be greater than said optimal thickness by a factor of 1/cos(γ) or close to 1/cos(γ).

11. The laser of claim 9, wherein the laser beam has a refractive angle γ within the quantum dot structure;
the quantum well gain chip defining a quantum dot structure, the quantum dot structure having a thickness, the thickness of the quantum dot structure having some optimal thickness when employed for normal incidence of the laser beam, the thickness of the quantum dot structure selected to be greater than said optimal thickness by a factor of 1/cos(γ) or close to 1/cos(γ).

12. The laser of claim 6, wherein the transparent layer material is SiC or diamond.

13. The laser of claim 6 comprising at least one additional element in the laser cavity giving rise to intracavity harmonic generation.

14. The laser of claim 13 wherein the intracavity harmonic generation is second harmonic generation or third harmonic generation.

15. The laser of claim 13 wherein the laser runs in single longitudinal mode.

16. The laser of claim 6, wherein the tilt angle of the gain chip is at or close to Brewster angle.

17. The laser of claim 16, wherein the gain chip is a quantum well gain chip.

18. The laser of claim 17, wherein the quantum well gain chip does not require a resonant periodic gain architecture.

19. The laser of claim 16, wherein the gain chip is a quantum dot gain chip.

20. The laser of claim 17, wherein the laser beam has a refractive angle γ within the quantum well structure;
the quantum well gain chip defining a quantum well structure, the quantum well structure having a thickness, the thickness of the quantum well structure having some optimal thickness when employed for normal incidence of the laser beam, the thickness of the quantum well structure selected to be greater than said optimal thickness by a factor of 1/cos(γ) or close to 1/cos(γ).

21. The laser of claim 19, wherein the laser beam has a refractive angle γ within the quantum dot structure;
the quantum well gain chip defining a quantum dot structure, the quantum dot structure having a thickness, the thickness of the quantum dot structure having some optimal thickness when employed for normal incidence of the laser beam, the thickness of the quantum dot structure selected to be greater than said optimal thickness by a factor of 1/cos(γ) or close to 1/cos(γ).

22. The laser of claim 16, wherein the transparent layer material is SiC or diamond.

23. The laser of claim 16 comprising at least one additional element in the laser cavity giving rise to intracavity harmonic generation.

24. The laser of claim 23, wherein the intracavity harmonic generation is second harmonic generation or third harmonic generation.

25. The laser of claim 23 wherein the laser runs in single longitudinal mode.

26. An optically pumped or electrically pumped semiconductor laser comprising a laser cavity;
at least one gain chip disposed within the laser cavity;
the at least one gain chip having at least one transparent layer;
a volume Bragg grating (VBG) disposed within the laser cavity;
the VBG having a bandwidth;
the bandwidth of the VBG selected to be less than 0.8F, where F is the minimum free spectral range of etalons formed by the at least one transparent layer.

27. The laser of claim 26, wherein the gain chip is a quantum well gain chip or a quantum dot gain chip.

28. The laser of claim 27, wherein the gain chip is not a resonant periodic gain (RPG) structure.

29. The laser of claim 26, wherein the transparent layer material is SiC or diamond.

30. The laser of claim 26 comprising at least one additional element in the laser cavity giving rise to intracavity harmonic generation.

31. The laser of claim 30, wherein the intracavity harmonic generation is second harmonic generation or third harmonic generation.

32. The laser of claim 30 wherein the laser runs in single longitudinal mode.

33. The laser of claim 6 further comprising a volume Bragg grating (VBG) disposed within the laser cavity.

34. The laser of claim 33, wherein the gain chip is a quantum well gain chip.

35. The laser of claim 34, wherein the quantum well gain chip is not a resonant periodic gain (RPG) structure.

36. The laser of claim 33, wherein the gain chip is a quantum dot gain chip.

37. The laser of claim 34, wherein the laser beam has a refractive angle γ within the quantum well structure;
the quantum well gain chip defining a quantum well structure, the quantum well structure having a thickness, the thickness of the quantum well structure having some optimal thickness when employed for normal incidence of the laser beam, the thickness of the quantum well structure selected to be greater than said optimal thickness by a factor of 1/cos(γ) or close to 1/cos(γ).

38. The laser of claim 36, wherein the laser beam has a refractive angle γ within the quantum dot structure;
the quantum well gain chip defining a quantum dot structure, the quantum dot structure having a thickness, the thickness of the quantum dot structure having some optimal thickness when employed for normal incidence of the laser beam, the thickness of the quantum dot structure selected to be greater than said optimal thickness by a factor of 1/cos(γ) or close to 1/cos(γ).

39. The laser of claim 33, wherein the transparent layer material is SiC or diamond.

40. The laser of claim 33 comprising at least one additional element in the laser cavity giving rise to intracavity harmonic generation.

41. The laser of claim 40, wherein the intracavity harmonic generation is second harmonic generation or third harmonic generation.

42. The laser of claim 40 wherein the laser runs in single longitudinal mode.

43. The laser of claim 33, wherein the tilt angle of the gain chip is at or close to Brewster angle.

44. The laser of claim 43, wherein the gain chip is a quantum well gain chip.

45. The laser of claim 44, wherein the quantum well gain chip does not require a resonant periodic gain architecture.

46. The laser of claim 43, wherein the gain chip is a quantum dot gain chip.

47. The laser of claim 44, wherein the laser beam has a refractive angle γ within the quantum well structure;
the quantum well gain chip defining a quantum well structure, the quantum well structure having a thickness, the thickness of the quantum well structure having some optimal thickness when employed for normal incidence of the laser beam, the thickness of the quantum well structure selected to be greater than said optimal thickness by a factor of 1/cos(γ) or close to 1/cos(γ).

48. The laser of claim 46, wherein the laser beam has a refractive angle γ within the quantum dot structure;
the quantum well gain chip defining a quantum dot structure, the quantum dot structure having a thickness, the thickness of the quantum dot structure having some optimal thickness when employed for normal incidence of the laser beam, the thickness of the quantum dot structure selected to be greater than said optimal thickness by a factor of 1/cos(γ) or close to 1/cos(γ).

49. The laser of claim 43, wherein the transparent layer material is SiC or diamond.

50. The laser of claim 43 comprising at least one additional element in the laser cavity giving rise to intracavity harmonic generation.

51. The laser of claim 50, wherein the intracavity harmonic generation is second harmonic generation or third harmonic generation.

52. The laser of claim 50 wherein the laser runs in single longitudinal mode.

53. An optically pumped or electrically pumped semiconductor laser comprising a laser cavity;
at least one gain chip disposed within the laser cavity;
the at least one gain chip having at least one transparent layer;
the laser cavity also comprising a narrow bandpass filter, the filter having a bandwidth B₂,
wherein B₂ is selected to be less than 0.8F₂, where F₂ is the minimum free spectral range of etalons formed by the at least one transparent layer.

54. The laser of claim 53, wherein the gain chip is a quantum well gain chip or a quantum dot gain chip.

55. The laser of claim 54, wherein the gain chip is not a resonant periodic gain (RPG) structure.

56. The laser of claim 53, wherein the transparent layer material is SiC or diamond.

57. The laser of claim 53 comprising at least one additional element in the laser cavity giving rise to intracavity harmonic generation.

58. The laser of claim 57, wherein the intracavity harmonic generation is second harmonic generation or third harmonic generation.

59. The laser of claim 57 wherein the laser runs in single longitudinal mode.

60. The laser of claim 6 further comprising a narrow bandpass filter disposed within the laser cavity.

61. The laser of claim 60, wherein the gain chip is a quantum well gain chip.

62. The laser of claim 61, wherein the quantum well gain chip is not a resonant periodic gain (RPG) structure.

63. The laser of claim 60, wherein the gain chip is a quantum dot gain chip.

64. The laser of claim 61, wherein the laser beam has a refractive angle γ within the quantum well structure;
the quantum well gain chip defining a quantum well structure, the quantum well structure having a thickness, the thickness of the quantum well structure having some optimal thickness when employed for normal incidence of the laser beam, the thickness of the quantum well structure selected to be greater than said optimal thickness by a factor of 1/cos(γ) or close to 1/cos(γ).

65. The laser of claim 63, wherein the laser beam has a refractive angle γ within the quantum dot structure;
the quantum well gain chip defining a quantum dot structure, the quantum dot structure having a thickness, the thickness of the quantum dot structure having some optimal thickness when employed for normal incidence of the laser beam, the thickness of the quantum dot structure selected to be greater than said optimal thickness by a factor of 1/cos(γ) or close to 1/cos(γ).

66. The laser of claim 60, wherein the transparent layer material is SiC or diamond.

67. The laser of claim 60 comprising at least one additional element in the laser cavity giving rise to intracavity harmonic generation.

68. The laser of claim 67, wherein the intracavity harmonic generation is second harmonic generation or third harmonic generation.

69. The laser of claim 67 wherein the laser runs in single longitudinal mode.

70. The laser of claim 60, wherein the tilt angle of the gain chip is at or close to Brewster angle.

71. The laser of claim 70, wherein the gain chip is a quantum well gain chip.

72. The laser of claim 71, wherein the quantum well gain chip is not a resonant periodic gain (RPG) structure.

73. The laser of claim 70, wherein the gain chip is a quantum dot gain chip.

74. The laser of claim 71, wherein the laser beam has a refractive angle γ within the quantum well structure;
the quantum well gain chip defining a quantum well structure, the quantum well structure having a thickness, the thickness of the quantum well structure having some optimal thickness when employed for normal incidence of the laser beam, the thickness of the quantum well structure selected to be greater than said optimal thickness by a factor of 1/cos(γ) or close to 1/cos(γ).

75. The laser of claim 73, wherein the laser beam has a refractive angle γ within the quantum dot structure;
the quantum well gain chip defining a quantum dot structure, the quantum dot structure having a thickness, the thickness of the quantum dot structure having some optimal thickness when employed for normal incidence of the laser beam, the thickness of the quantum dot structure selected to be greater than said optimal thickness by a factor of 1/cos(γ) or close to 1/cos(γ).

76. The laser of claim 70, wherein the transparent layer material is SiC or diamond.

77. The laser of claim 70 comprising at least one additional element in the laser cavity giving rise to intracavity harmonic generation.

78. The laser of claim 77, wherein the intracavity harmonic generation is second harmonic generation or third harmonic generation.

79. The laser of claim 77 wherein the laser runs in single longitudinal mode.
